(19) United States
(12) Patent Application Publication
(10) Pub. No.: US 2020/0288598 A1
(43) Pub. Date: Sep. 10, 2020

(54) ELECTRONICS COOLING USING BIMETAL

(71) Applicant: Byton North America Corporation, Santa Clara, CA (US)

(72) Inventors: Meisam MEHRAVARAN, Los Gatos, CA (US); Sungyong BANG, Troy, MI (US)

(21) Appl. No.: 16/297,074

(22) Filed: Mar. 8, 2019

(51) Int. Cl. H05K 7/20; F16K 31/00

(52) U.S. Cl. CPC H05K 7/20145; H05K 7/20863; F16K 31/002

(57) ABSTRACT

Embodiments are disclosed of an apparatus including a first enclosure having an interior that is at a first temperature and a second enclosure having an interior that is at a second temperature. An opening allows fluid to flow between the interior of the first enclosure and the interior of the second enclosure. A bimetal valve is positioned in the opening to regulate fluid flow between the first enclosure and the second enclosure depending on the first temperature or on the difference between the first temperature and the second temperature.

### TECHNICAL FIELD

The disclosed embodiments relate generally to cooling systems and in particular, but not exclusively, to a cooling system using bimetal elements.

### BACKGROUND

Modern cooling systems have become quite complex. Typically they involve multiple temperature sensors that are coupled by wire to a central computer or controller. The central computer is also coupled to a cooling or heating source or to motors, solenoids, or other activation mechanisms that can directly flow from a cooling or heating source to the area that requires heating or cooling, as determined by the central computer based on input received from its multiple temperature sensors.

Although they work well, these modern cooling systems have various disadvantages. The large number of components, and the labor involved in their installation and tuning, makes the systems more expensive. The large number of components also decreases system reliability, because with more components in the system there is a higher probability of a component failure.

### SUMMARY

Embodiments are disclosed of an apparatus including a first enclosure having an interior that is at a first temperature and a second enclosure having an interior that is at a second temperature. An opening allows fluid to flow between the interior of the first enclosure and the interior of the second and enclosure. A bimetal valve is positioned in the opening to regulate fluid flow between the first enclosure and the second enclosure depending on the first temperature or on the difference between the first temperature and the second temperature.

Embodiments are disclosed of a system that includes a vehicle. An electronics compartment is positioned within the vehicle, and an interior of the electronics compartment is at a first temperature. A cooling duct is positioned within the vehicle, and the interior of the cooling duct is at a second temperature. An opening allows fluid to flow from the cooling duct into the electronics. A bimetal valve positioned in the opening regulates fluid flow between the cooling duct and the electronics compartment depending on the first temperature or on the difference between the first temperature and the second temperature.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIGS. 1A-1B are schematic drawings of an embodiment of a cooling system.

FIGS. 2A-2D are schematic drawings of an embodiment of a bimetal valve in the cooling system of FIGS. 1A-1B.

FIGS. 3A-3B are schematic drawings of another embodiment of a bimetal valve in the cooling system of FIGS. 1A-1B.

FIGS. 4A-4B are schematic drawings of another embodiment of a bimetal valve in the cooling system of FIGS. 1A-1B.

FIG. 5 is a plan view schematic of a vehicle illustrating an embodiment of a vehicle application of the cooling system of FIGS. 1A-1B.

### DETAILED DESCRIPTION

Embodiments are disclosed of a cooling system that includes a bimetal valve to regulate the flow of cooling fluid into an enclosure with heat-generating components such as electronics. The bimetal valve automatically directs cooling air into the enclosure when needed, thus eliminating the need for complex and expensive computers, sensors and their associated wiring and software.

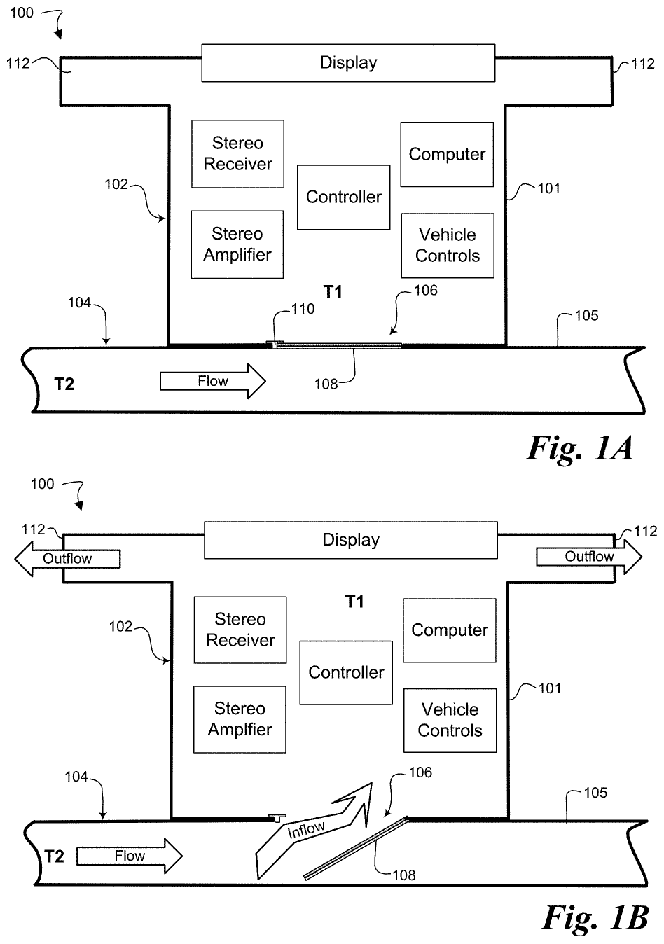

FIGS. 1A-1B illustrate an embodiment of cooling system 100 including a bimetal valve 108; FIG. 1A illustrates the bimetal valve when closed, FIG. 1B when open. System 100 includes a first enclosure 102 and a second enclosure 104. An opening 106 permits a fluid (e.g. air) such as air in one embodiment, to flow between the first and second enclosures. As used in this application the meaning of the term “fluid” is the meaning used in physics: a fluid can be any material or substance capable of flowing, which can include liquids, gases, and plasmas. In an embodiment where the fluid is a gas, the fluid can be a gas mixture such as air, but in other embodiments the fluid can be a pure gas, such as nitrogen. In an embodiment where the fluid is a liquid, the fluid can be water, automotive anti-freeze (mostly ethylene glycol), or some other liquid with the desired thermal characteristics. A bimetal valve 108 is positioned in opening 106 block or unblock the opening, thus regulating the flow of fluid between first enclosure 102 and second enclosure 104.

First enclosure 102 is bounded by a housing or other combination of impermeable surfaces 101 and has an interior within which the fluid, air in one embodiment, is at temperature T1. The interior of first enclosure 102 can have therein at least one heat-generating component. In an embodiment in which first enclosure 102 is an electronics compartment in a vehicle, the heat-generating components can include one or more of the illustrated components: a stereo receiver, a stereo amplifier, a controller, a computer, and vehicle control electronics. Some heat-generating components can be partially in the interior of first enclosure 102 and partially outside. A display, for instance, can have its screen outside the enclosure where a user can see it while having other parts of the display within the enclosure. Opening 106, when not blocked by bimetal valve 108, permits fluid to flow in or out of first enclosure 102, while one or more outlets 112 allow fluid to flow out of first enclosure 102.

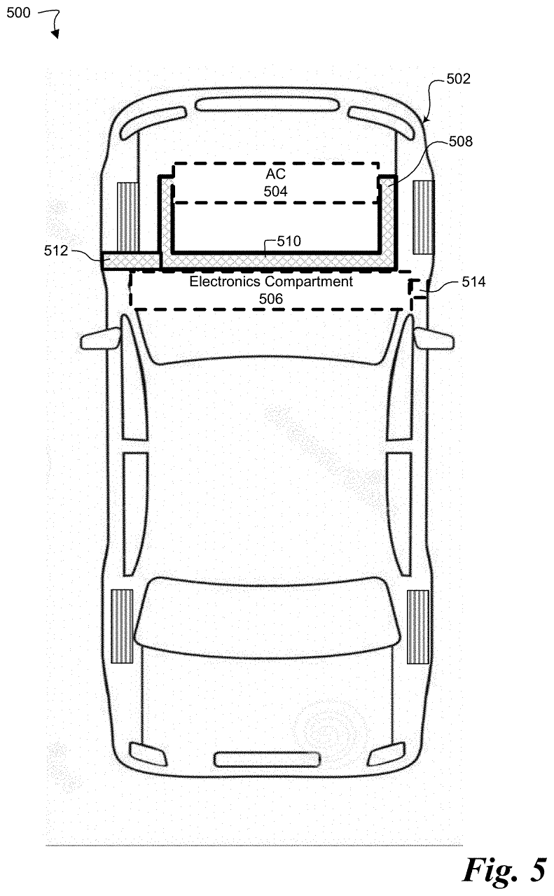

Second enclosure 104 is bounded by a housing or other combination of solid surfaces 105 and has an interior within which the fluid, air in one embodiment, is at temperature T2. Fluid in second enclosure 104 can be at a higher or lower pressure than the fluid in first enclosure 102 and/or can be made to flow through the enclosure, for instance by a fan or pump (not shown) coupled to the second enclosure. In a vehicle embodiment, second enclosure 104 can be a cooling duct coupled to the vehicle's air conditioning system, or can be a duct that collects atmospheric air from outside the vehicle (see, e.g., FIG. 5).

Second enclosure 104 is fluidly coupled to first enclosure 102 by opening 106. Opening 106 allows fluid to flow between the first and second enclosures. In one embodiment fluid can flow from the first to the second enclosure, but in other embodiments the fluid can flow the other way, from the second enclosure to the first. In still other embodiments, fluid can flow both ways. In the illustrated embodiment second enclosure 104 is adjacent to first enclosure 102, such that opening 106 is formed by alignment of an opening in housing 101 with a similar opening in housing 105. But other embodiments can have different configurations of opening 106. In one embodiment, for instance, opening 106 can be a duct or other fluid conduit between first enclosure 102 and second enclosure 104.

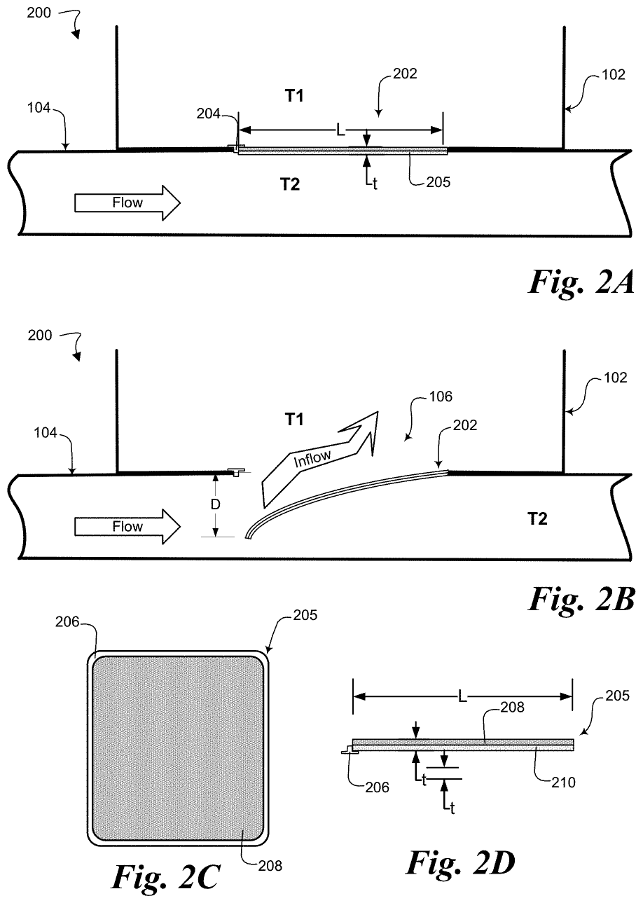

A bimetal valve 108, together with a seal 110 around all or part of its perimeter, cover opening 106; when closed the bimetal valve 108 prevents fluid from flowing between the first and second enclosures, but when open the bimetal valve permits fluid to flow between the first and second enclosures. Bimetal valve 108 includes a bimetal element that is designed to open or close automatically based on the temperature difference between the interiors of the first and second enclosures—i.e., based on T1−T2. Generally, the design of bimetal valve 108 can take into account one or more of the following factors:
The temperature range ΔT in which the door will be used.
The maximum temperature the door will experience.
Movement, force, or both movement and force, required of the door.
Space limitations.
Service conditions.
   Embodiments of bimetal valve 108 are described below in connection with FIGS. 2A-2B, 3A-3B, and 4A-4B.

In one embodiment of operation of cooling system 100, the temperature inside first enclosure 102 is T1 and the temperature inside second enclosure 104 is T2, with T2 less than T1. The fluid in second enclosure 104 can be pressurized or made to flow with a fan or pump (not shown) coupled to the second enclosure. Initially bimetal valve 108 is closed, as shown in FIG. 1A, so that no fluid can flow between the first and second enclosures. The one or more heat generating components in the interior of first enclosure 102 heat the fluid in the interior, so that temperature T1 slowly increases over time and the temperature difference ΔT=T1−T2 between the first and second enclosures slowly increases. As temperature difference ΔT increases, bimetal valve 108 opens, as shown in FIG. 1B, so that there is an inflow of cooler fluid from second enclosure 104 into first enclosure 102 through opening 106. The cooler fluid flowing into first enclosure 102 flows over the heat-generating components, which transfer heat to the flowing fluid. The fluid then flows out of first enclosure 102 through outlets 112, carrying the heat extracted from the heat-generating components out of the enclosure.

Because T2 is lower than T1, as fluid flows from second enclosure 104 into first enclosure 102 and extracts heat from the heat-generating components inside, temperature T1 will begin to fall and ΔT decreases. As ΔT decreases, bimetal valve 108 closes until it returns to its fully-closed position, as shown in FIG. 1A, at which time the heating/cooling cycle begins again. Hence bimetal valve 108 regulates the flow of cooling air into first enclosure 102, thus also regulating temperature T1.

Other embodiments of operation of system 100 are also possible. For instance, in another embodiment the pressure in second enclosure 104 can be kept lower than the pressure in first enclosure, so that when bimetal valve 108 opens air is drawn into first enclosure 102 through outlets 112 and exits though opening 106 into second enclosure 104. In other words, such an embodiment would reverse the flow direction compared to the other embodiment described above.

FIGS. 2A-2D together illustrate an embodiment of a cooling system 200 with a bimetal valve 202. FIGS. 2A and 2B show system 200 with bimetal valve 202 in its closed and open positions, respectively, while FIGS. 2C-2D illustrate an embodiment of the construction of bimetal valve 202. Cooling system 200 is substantially similar to cooling system 100: as before, opening 106 between first enclosure 102 and second enclosure is covered by bimetal valve 202, aided by seal 204. The primary difference between cooling systems 100 and 200 is the embodiment of bimetal valve 202.

Bimetal valve 202 is fixed to an edge of opening 106 and is a door 205 having substantially the same shape as opening 106. As shown in FIGS. 2C-2D, door 205 is formed from a pair of layers 208 and 210 laminated together. Layers 208 and 210 are made of different materials—typically but not necessarily metals or metal alloys—having different coefficients of thermal expansion, so that upon being exposed to an increase in temperature the metals expand by a different amount, thus deforming the door. In another embodiment, door 205 can be made partially of bimetal and partially of a non-bimetal material, so that deflection of the bimetal part deflects the non-bimetal part, thus opening and closing bimetal valve 202. Bimetal laminates that can be used in bimetal valve 202 are commercially available, for instance from Engineered Material Solutions of Attleboro, Mass., USA.

To help bimetal valve 202 prevent fluid flow between the first and second enclosures, a seal 204 can be fixed around the perimeter of opening 106. Alternatively, a seal 206 can be fixed around the perimeter of bimetal valve 202. In still other embodiments a multi-part seal including seal 204 and seal 206 can be used.

In one embodiment, cooling system 200 operates similarly to cooling system 100. Initially bimetal valve 202 is closed, as shown in FIG. 2A, so that no fluid flows between the first and second enclosures. The one or more heat generating components in the interior of first enclosure 102 heat the fluid in the interior, so that temperature T1 slowly increases and the temperature difference ΔT=T1−T2 between the first and second enclosures slowly increases. As temperature difference ΔT increases, door 205 deforms as the different material layers 208 and 210 that form the door expand by different amounts in response to the temperature increase. As door 205 deforms, its free end (the end opposite where it is fixed to an edge of opening 106) deflects by a distance D, as shown in FIG. 2B, unsealing opening 106 and allowing an inflow of cooler fluid from second enclosure 104 into first enclosure 102 through opening 106. Deflection distance D will depend mostly on temperature difference ΔT and on the particular combination of materials used to build door 205. For an embodiment with a cantilever-type door such as door 205, deflection distance D can be calculated according to the formula:

$$D = \frac{0.53 F ( T 2 - T 1 ) {L}^{2}}{t} ,$$

where F is the flexivity of the door (e.g., (in/in)/(° F.)); T2−T1 is the temperature change in ° F., L is the length of the door, and t is the door's thickness. Depending on the materials used, in one embodiment the useful deflection temperature change for door 205 can be from −70° C. to 540° C., although the exact range can also depend on the dimensions of the materials used. Once door 205 opens, the cooler fluid flowing into first enclosure flows over the heat-generating components, which transfer heat to the flowing fluid. The flowing fluid then exits first enclosure 102 through outlets 112, carrying the heat extracted from the heat-generating components out of the enclosure.

Because T2 is lower than T1, as fluid flows from second enclosure 104 into first enclosure 102 and extracts heat from the heat-generating components inside, temperature T1 will begin to fall and ΔT decreases. As ΔT decreases, door 205 again deforms, but in the opposite direction, until it returns to its fully-closed state (i.e., D=0) as shown in FIG. 1A, at which time the heating/cooling cycle begins again. Hence bimetal valve 108 regulates the flow of cooling air into first enclosure 202, thus also regulating temperature T1.

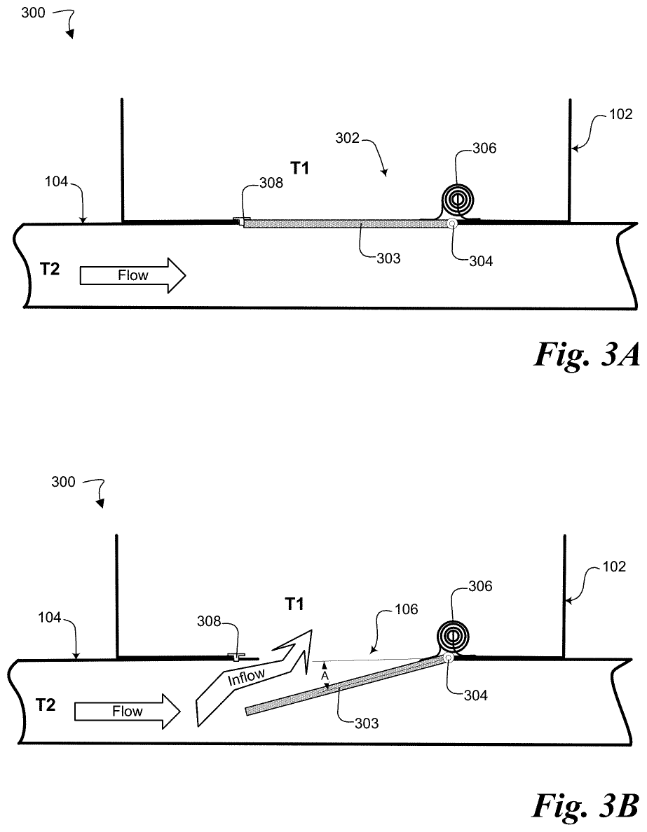

FIGS. 3A-3B together illustrate an embodiment of a cooling system 300. FIG. 3A shows system 300 with its bimetal valve 302 in the closed position, FIG. 3B in the open position. Cooling system 300 is substantially similar to cooling system 200: as before, opening 106 between first enclosure 102 and second enclosure is covered by bimetal valve 302, aided by seal 308. The primary difference between systems 300 and 200 is the embodiment of bimetal valve 302.

In system 300, bimetal valve 302 includes a rigid door 303 coupled to a bimetal coil 306. Rigid door 303 has substantially the same shape as opening 106 and can formed from metals or non-metals. The rigid door is coupled by a hinge 304 to an edge of opening 106. To help bimetal valve 302 prevent fluid flow between the first and second enclosures, a seal 308 can be fixed around the perimeter of opening 106 or fixed around the perimeter of rigid door 303. Bimetal coil 306 is coupled to one of the walls of first enclosure 102 and also coupled to rigid door 303. Bimetal coil is a coil formed from multiple layers of materials—typically but not necessarily metals or metal alloys—with different coefficients of thermal expansion, such that when heated the bimetal coil converts the different expansions of the two metals into a rotational motion. Bimetal coils are commercially available, for instance from Engineered Material Solutions of Attleboro, Mass., USA.

In one embodiment, cooling system 300 operates similarly to cooling systems 100 and 200, although because bimetal coil 306 is entirely within first enclosure 102 its operation depends more heavily on temperature T1 instead of on the temperature difference ΔT=T1−T2. Initially bimetal valve 302 is closed, as shown in FIG. 3A, so that no fluid flows between the first and second enclosures. The one or more heat generating components in the interior of first enclosure 102 heat the fluid in the interior, so that temperature T1 slowly increases over time, as does temperature difference ΔT between the first and second enclosures. As T1 increases, bimetal coil 306 slowly deforms and, as it does, it rotates door 303 about hinge 304. As door 303 rotates about hinge 304, its free end (i.e., the end opposite hinge 304) deflects by an angle A, as shown in FIG. 3B, unsealing opening 106 and allowing an inflow of cooler fluid from second enclosure 104 into first enclosure 102 through opening 106. Deflection angle A will depend mostly on the change in temperature T1 to which bimetal coil 306 is exposed and on the particular combination of materials used to build bimetal coil 306. For an embodiment with a bimetal coil 306, deflection angle A can be calculated according to the formula:

$$A = \frac{67 F ( T 2 - T 1 ) L}{t} ,$$

where F is the flexivity of the door (e.g., (in/in)/(° F.)); T2−T1 is the temperature change in ° F., L is the length of the coil (i.e., the full length of the material measured along coil, or the length of the coiled material if uncoiled), and t is the thickness of the coil material. Depending on the materials used, in one embodiment the useful deflection temperature change for coil 306 can be from −70° C. to 540° C., although the exact range can also depend on the dimensions of the materials used. Once bimetal coil 306 deflects through angle A and opens door 303, the cooler fluid flowing into first enclosure flows over the heat-generating components, which transfer heat to the flowing fluid. The flowing fluid the flows out of first enclosure 102 through outlets 112, carrying the heat extracted from the heat-generating components out of the enclosure.

Because T2 is lower than T1, as fluid flows from second enclosure 104 into first enclosure 102 and extracts heat from the heat-generating components inside, temperature T1 will begin to fall and ΔT decreases. As T1 decreases, bimetal coil 306 deforms the opposite way until it returns to its fully-closed state (i.e., D=0) as shown in FIG. 3A, at which time the heating/cooling cycle begins again. Hence bimetal valve 302 regulates the flow of cooling air into first enclosure 102, thus also regulating temperature T1.

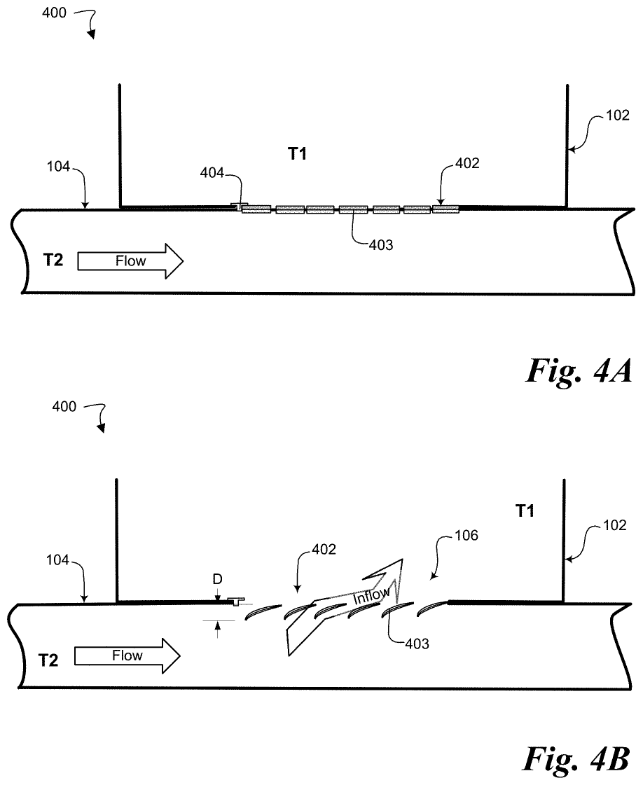

FIGS. 4A-4B together illustrate an embodiment of a cooling system 400. FIG. 4A shows system 400 with its bimetal valve in the closed position, FIG. 4B in the open position. Cooling system 400 is substantially similar to cooling system 200: as before, opening 106 between first enclosure 102 and second enclosure 104 is covered by a bimetal valve 402. The primary difference between cooling systems 200 and 400 is the construction of bimetal valve 402. In system 400, bimetal valve 402 is a door having substantially the same shape as opening 106 and surrounded by a seal 404 that can be fixed to the edges of opening 106. But rather than being a single unit like door 205, bimetal valve 402 is a louvered door made up of multiple small sections or slats 403. Each section 403 has substantially the same construction as door 205 and operates substantially as described above in connection with system 200.

FIG. 5 illustrates a vehicle system 500 using an embodiment of a cooling system such as cooling systems 200, 300, or 400 shown and described above. In vehicle system 500, a vehicle 502 includes an air conditioning (AC) system 504 and an electronics compartment 506. Electronics compartment 506 is shown as a single compartment in the vehicle's dashboard, but in other embodiments there can be multiple electronics compartments and they need not all be in the same place in vehicle 502. Air conditioning system 504 is coupled to a duct 508 that runs between the air conditioning system 504 and electronics compartment 506. A portion 510 of duct 508 is near electronics compartment 506, so that in system 500 electronics compartment 506 is analogous to the first enclosure and portion 510 of duct 508 is analogous to the second enclosure of cooling system 200, 300, or 400. A bi-metal valve (not visible in this figure, but see systems 200, 300, or 400) then regulates the flow of air between duct portion 510 and electronics compartment 506. Duct 508 can also include one or more portions 512 that extend to the exterior of the vehicle. Similarly, electronics compartment 506 can include a duct 514 that extends to the exterior of the vehicle. Duct 512 allows exterior air to be used for cooling, and duct 514 allows warm air from electronics compartment 506 to be vented outside the vehicle. (i.e., duct 514 is analogous to outlet 112 in system 100).

The above description of embodiments is not intended to be exhaustive or to limit the invention to the described forms. Specific embodiments of, and examples for, the invention are described herein for illustrative purposes, but various modifications are possible.

What is claimed is:

1. An apparatus comprising:
a first enclosure having an interior that is at a first temperature;
a second enclosure having an interior that is at a second temperature;
an opening to allow fluid to flow between the interior of the first enclosure and the interior of the second enclosure; and
a bimetal valve positioned in the opening to regulate fluid flow between the first enclosure and the second enclosure depending on the first temperature or on the difference between the first temperature and the second temperature.

2. The apparatus of claim 1 wherein the bimetal valve is a bimetal door that is fixed to an edge of the opening and deforms in response to the difference between the first temperature and the second temperature.

3. The apparatus of claim 2 wherein the first temperature is higher than the second temperature and fluid flows from the second enclosure to the first enclosure when the bimetal door opens.

4. The apparatus of claim 2 wherein the bimetal door is formed from a sheet of a first metal laminated to a sheet of a second metal, the first and second metals having different coefficients of thermal expansion.

5. The apparatus of claim 2 wherein the bimetal door is surrounded by a flexible seal that engages at least one edge of the opening.

6. The apparatus of claim 1 wherein the bimetal valve is a rigid door that is hinged to an edge of the opening and coupled to a bimetal coil, so that the bimetal coil rotates the rigid door about the hinge in response to the difference between the first temperature and the second temperature.

7. The apparatus of claim 6 wherein the first temperature is higher than the second temperature and fluid flows from the second enclosure to the first enclosure when the rigid door opens.

8. The apparatus of claim 6 wherein the rigid door is surrounded by a seal that engages with at least one edge of the opening.

9. The apparatus of claim 1 wherein the first enclosure has at least one heat-generating component in its interior.

10. A system comprising:
a vehicle;
an electronics compartment positioned within the vehicle, an interior of the electronics compartment being at a first temperature;
a cooling duct positioned within the vehicle, an interior of the cooling duct being at a second temperature;
an opening to allow fluid to flow from the cooling duct into the electronics ; and
a bimetal valve positioned in the opening to regulate fluid flow between the cooling duct and the electronics compartment depending on the first temperature or on the difference between the first temperature and the second temperature.

11. The system of claim 1 wherein the bimetal valve is a bimetal door that is fixed to an edge of the opening and deforms in response to the difference between the first temperature and the second temperature.

12. The system of claim 2 wherein the bimetal door is formed from a sheet of a first metal laminated to a sheet of a second metal, the first and second metals having different coefficients of thermal expansion.

13. The system of claim 2 wherein the bimetal door is surrounded by a flexible seal that engages at least one edge of the opening.

14. The system of claim 1 wherein the bimetal valve is a rigid door that is hinged to an edge of the opening and coupled to a bimetal coil, so that the bimetal coil rotates the rigid door about the hinge in response to the difference between the first temperature and the second temperature.

15. The system of claim 6 wherein the first temperature is higher than the second temperature and fluid flows from the second enclosure to the first enclosure when the rigid door opens.

16. The system of claim 6 wherein the rigid door is surrounded by a seal that engages with at least one edge of the opening.

17. The system of claim 1 wherein the first enclosure has at least one heat-generating component in its interior.
